(19) United States
(12) Patent Application Publication
(10) Pub. No.: US 2024/0047935 A1
(43) Pub. Date: Feb. 8, 2024

(54) METHOD FOR PRODUCING A PLURALITY OF SEMICONDUCTOR LASERS AND SEMICONDUCTOR LASER

(71) Applicant: ams-OSRAM International GmbH, Regensburg (DE)

(72) Inventors: Lars NÄHLE, Bad Abbach (DE); Sven GERHARD, Alteglofsheim (DE)

(73) Assignee: ams-OSRAM International GmbH, Regensburg (DE)

(21) Appl. No.: 18/546,148

(22) PCT Filed: Jan. 27, 2022
(86) PCT No.: PCT/EP2022/051854

§ 371 Date: Aug. 11, 2023

(30) Foreign Application Priority Data
Feb. 15, 2021 (DE) 10 2021 103 484.1

(51) Int. Cl. H01S 5/02; H01S 5/22; H01S 5/10

(52) U.S. Cl. CPC H01S 5/0203; H01S 5/22; H01S 5/10

(57) ABSTRACT

The invention relates to a method for producing a plurality of semiconductor lasers, including the steps of: a) providing a substrate having a semiconductor layer sequence and having a plurality of component regions, each component region having at least one resonator region and being delimited perpendicular to the resonator region by singulation lines in the transverse direction and being delimited parallel to the resonator region by singulation lines in the longitudinal direction; b) forming recesses which overlap with the singulation lines in the transverse direction, using a dry-chemical etching method, wherein, when the substrate is seen from above, the recesses have in each case at least one transition, at which a first section of a side face of the recess and a second section of the side face of the recess form an angle of more than 180° in the recess; c) wet-chemical etching of the side faces of the recesses for the purpose of forming resonator surfaces; and d) singulating the substrate along the singulation lines in the transverse direction and in the longitudinal direction. Additionally, a semiconductor laser is specified.

### CROSS-REFERENCE TO RELATED APPLICATIONS

The present application is a national stage entry from International Application No. PCT/EP2022/051854, filed on Jan. 27, 2022, published as International Publication No. WO 2022/171447 A1 on Aug. 18, 2022, and claims priority to German Patent Application No. 10 2021 103 484.1, filed Feb. 15, 2021, the disclosures of all of which are hereby incorporated by reference in their entireties.

### FIELD OF THE INVENTION

The present application relates to a method of manufacturing semiconductor lasers and to a semiconductor laser.

### BACKGROUND OF THE INVENTION

In the manufacturing of edge-emitting semiconductor lasers, such as semiconductor lasers emitting in the blue or ultraviolet spectral region, the facets that constitute the resonator surfaces of the semiconductor lasers are typically manufactured by scribing and breaking. However, this process is prone to variation, time-consuming, and costly.

One object is to achieve high-quality resonator surfaces reliably and cost-effectively.

This object is solved, inter alia, by a method and a semiconductor laser according to the independent claims. Further embodiments and usefulness are the subject of the dependent claims.

A method of manufacturing a plurality of semiconductor lasers is disclosed.

### SUMMARY OF THE INVENTION

According to at least one embodiment of the method, the method comprises a step of providing a substrate with a semiconductor layer sequence and with a plurality of device regions. A device region here corresponds, for example, to a region of the substrate with the semiconductor layer sequence from which a semiconductor laser emerges during manufacture.

For example, the semiconductor layer sequence has an active region provided for generating radiation, which is located between a first semiconductor layer of a first conductivity type and a second semiconductor layer of a second conductivity type different from the first conductivity type. For example, the active region is provided for generating radiation in the ultraviolet, visible or infrared spectral range.

The substrate is, for example, a growth substrate for the semiconductor layer sequence. However, the substrate can also be a carrier different from the growth substrate, which is applied to the semiconductor layer sequence before the singulation in semiconductor lasers, i.e. still in the wafer assembly.

According to at least one embodiment of the method, each device region comprises at least one resonator region. For example, each device region comprises exactly one resonator region or at least two resonator regions. A width of the resonator region, i.e. an extension of the resonator region in a lateral direction perpendicular to the resonator axis, is, for example, between 1 μm and 80 μm inclusive.

In particular, a resonator region is understood to be a region in which lateral guiding of the radiation propagating in the resonator between the resonator surfaces takes place. The radiation is, for example, index-guided or enhancement-guided (also referred to as gain-guided).

For example, the resonator region is a ridge waveguide. Alternatively, the resonator region is, for example, a region of the semiconductor laser in which the radiation propagates in gain-guided manner within the resonator, for example by means of a current flow limited in the lateral direction. In this case, lateral structuring of the semiconductor layer sequence to form an elevation is not required.

For example, each device region is respectively bounded by singulation lines in transverse direction and by singulation lines in the longitudinal direction. The singulation lines correspond to the points at which, in particular at the end of the method, singulation into the plurality of semiconductor lasers takes place.

Here, the longitudinal direction is considered to be a direction parallel to the main extension direction (or resonator axis) of the resonator region. In the finished semiconductor laser, the radiation generated in the active region oscillates along the resonator axis in the resonator region. The transverse direction extends perpendicular to the longitudinal direction.

According to at least one embodiment of the method, the method comprises a step in which recesses are formed that overlap with the singulation lines in transverse direction. In particular, the recesses are also located at a point where the resonator axis of the resonator region meets the singulation lines in transverse direction.

The recesses are produced, for example, by a dry chemical etching process, such as a plasma etching process. For this structuring of the semiconductor layer sequence, a lithographic process can be applied, for example using a photoresist mask or a hard mask. The recesses are formed, for example, in such a way that they extend in places through the semiconductor layer sequence. For example, the recesses also extend into the substrate.

For example, the recesses have a depth in the vertical direction, i.e. perpendicular to a main extension plane of the semiconductor layer sequence, of between 0.5 μm and 25 μm inclusive.

According to at least one embodiment of the method, the recesses each have at least one transition at which, in plan view of the substrate, a first section of a side face of the recess and a second section of the side face of the recess enclose an angle of more than 180° in the recess. In particular, the first section and the second section are immediately adjacent to each other. In particular, the first section is disposed closer to a resonator axis of the associated resonator region than the second section. For example, at least one such transition is associated with each device region or each resonator region. The first section extends, for example, in a straight line as viewed in transverse direction, i.e. without a kink or a bend, over the entire associated resonator region.

According to at least one embodiment of the method, the method comprises a step in which the side faces of the recesses for forming resonator surfaces are wet-chemically etched. By means of the wet chemical etching, material can be removed not only in the vertical direction but also in the lateral direction. Starting from the structuring in the form of recesses previously achieved by dry chemical etching, wet chemical etching can be used to expose crystal planes that run perpendicular to the longitudinal direction. During wet chemical etching, the mask used for the dry chemical etching process may already have been removed or may still be present on the semiconductor layer sequence.

According to at least one embodiment of the method, the method comprises a step in which the substrate is singulated along the singulation lines in transverse direction and in longitudinal directions. The singulation of the substrate is performed in particular subsequent to the dry chemical etching process and the wet chemical etching process. Thus, the resonator surfaces of the semiconductor laser are not formed during the singulation of the substrate, but are already formed in a preceding step. Chemical processes such as wet chemical or dry chemical etching, for example plasma etching, mechanical processes such as sawing or breaking and/or processes using laser radiation such as laser ablation or stealth dicing are suitable for the singulation.

In at least one embodiment of the method for manufacturing a plurality of semiconductor lasers, a substrate with a semiconductor layer sequence and with a plurality of device regions is provided, each device region having at least one resonator region and being bounded perpendicular to the resonator region by singulation lines in transverse direction and parallel to the resonator region by singulation lines in longitudinal direction. Recesses are formed which overlap with the singulation lines in transverse direction, in particular by a dry chemical etching process. The recesses each have at least one transition at which, in plan view of the substrate, a first section of a side face of the recess and a second section of the side face of the recess enclose an angle of more than 180° in the recess. The side faces of the recesses are wet-chemically etched to form resonator surfaces. The substrate is singulated along the singulation lines in transverse direction and in the longitudinal direction.

With the method described, resonator surfaces can be formed by a two-stage etching process, with the substrate being singulated only after the resonator surfaces have been formed. The singulation itself therefore no longer has any direct influence on the quality of the resonator surfaces. In particular, high-quality resonator surfaces can be produced with a high degree of efficiency and, compared with production by scribing and breaking, at low cost and with comparatively low variations.

It has turned out that particularly smooth resonator surfaces are obtained when the side faces of the recesses deviate from a linear course in the region of the transition, thereby creating an angle of more than 180° between the adjacent sections of the side faces. In other words, the transition is an opening transition, for example in the form of an opening bend. In this way, it can be achieved particularly reliably that during the wet chemical etching of the side faces, flat resonator surfaces are created which, with further etching time, can no longer be attacked by wet chemical etching due to the transition.

The wet chemical etching behavior is thus influenced in a targeted manner by the shape of the recesses in order to achieve particularly smooth resonator surfaces by etching.

An average roughness (rms roughness) of the resonator surfaces is, for example, at most 50 nm, preferably at most nm, particularly preferably at most 5 nm.

According to at least one embodiment of the method, the side faces of the recesses in the transition each run curved or kinked. In the case of a curved course, the angle in the region of the transition can be determined via a tangent of the side face, in particular in the second section. A curvature of the side faces in the region of the transition is convex, for example, as viewed from inside the recess.

According to at least one embodiment of the method, the transition, viewed in transverse direction from a resonator axis of the closest resonator region, is the first point of the side face at which the side face deviates from a straight course. This straight course is formed by the first section and runs in particular perpendicular to the resonator axis.

According to at least one embodiment of the method, the transition is arranged between a first partial region of the recess and a second partial region of the recess, the resonator surface being formed by means of the first partial region and the second partial region having, at least in places, a greater extent in the longitudinal direction than the first partial region. Such a second partial region may be arranged on only one side of the first partial region or on both sides of the first partial region, as viewed in transverse direction. Viewed in transverse direction, the second region is arranged, for example, to the side of the resonator region.

According to at least one embodiment of the method, the angle at the transition is between 180.001° and 359° inclusive. It has turned out that even a slight deviation from a straight line to larger angles at the point of the transition can result in a significant change in etching behavior during wet chemical etching. However, angles substantially greater than 180° may also be appropriate, for example angles between 181° and 270° inclusive, or even angles of at least 270°.

At an angle of more than 270°, the first partial region and the second partial region can overlap in places when viewed along the longitudinal direction. In this case, however, the second partial region is arranged without overlapping with the resonator region.

According to at least one embodiment of the method, a distance between the transition and the closest resonator region is at most 100 μm or at most 30 μm or at most 10 μm or at most 5 μm or at most 1 μm. It has turned out that the etching behavior changes significantly during wet chemical etching due to the transition, and this change has a long-distance effect over a length of several micrometers or more.

Expediently, the distance between the transition and the resonator region closest to it is at most so large that the desired low roughness is obtained over the entire width of the resonator surface to be fabricated.

According to at least one embodiment of the method, a crystal plane running perpendicular to the resonator region is exposed at least in the region of the resonator regions during wet chemical etching. This can be achieved, for example, by a wet chemical etching process which is characterized by a high selectivity with respect to the crystal directions.

According to at least one embodiment of the method, the semiconductor layer sequence is based on a nitride compound semiconductor material.

For example, wet chemical etching exposes at least in places a (1-100) plane or a (10-10) plane of the semiconductor layer sequence. These planes are also referred to as m-plane.

For nitride compound semiconductor material, for example, a basic solution through which OH⁻ ions are formed is suitable. For example, KOH, TMAH or NH₃ can be used.

Based on “nitride compound semiconductor material” means in the present context that the semiconductor layer sequence or at least a part thereof, particularly preferably at least the active region and/or the growth substrate, comprises or consists of a nitride compound semiconductor material, preferably AlₓIn_{y}Ga_{1-x-y}N, where 0≤x≤1, 0≤y≤1 and x+y≤1. This material does not necessarily have to have a mathematically exact composition according to the above formula. Rather, it may have, for example, one or more dopants as well as additional constituents. For the sake of simplicity, however, the above formula contains only the essential constituents of the crystal lattice (Al, Ga, In, N), even if these may be partially replaced and/or supplemented by small amounts of other substances.

An active region based on nitride compound semiconductor material can generate radiation in the ultraviolet, blue or green spectral range with high efficiency.

It has turned out that particularly smooth resonator surfaces can also be achieved with semiconductor layers of the active region based on nitride compound semiconductor material with a comparatively large indium content, for example with an indium content y between 0.10 and 0.35 inclusive. Such an indium content of the active region is suitable, for example, for generating radiation in the blue or green spectral range.

However, the method described is also suitable for nitride compound semiconductor material with lower indium content and indium-free nitride compound semiconductor material. Furthermore, the method is also suitable for other semiconductor materials, in particular other III-V compound semiconductor materials such as AlₓIn_{y}Ga_{1-x-y}SbᵤAsᵥP₁₋ᵤ₋ᵥ, for example for yellow to red radiation or infrared radiation. Here, in each case 0≤x≤1, 0≤y≤1 and x+y≤1, 0≤u≤1, 0≤v≤1 and u+v≤1, in particular also with x≠1, y≠1, u≠1, v≠1, x≠0, y≠0, u≠0 and/or v≠0.

According to at least one embodiment of the method, the recesses are formed by the dry chemical etching process in such a way that they are spaced apart from the singulation lines in the longitudinal direction, for example by at least 1 μm. In this case, therefore, the recesses do not extend continuously across adjacent device regions.

According to at least one embodiment of the method, the recesses between adjacent device regions extend continuously along the singulation lines in the longitudinal direction. In other words, the recesses extend continuously along the singulation lines in transverse direction across a plurality of device regions or even across all device regions of the substrate along that direction. For example, the recesses are trench-shaped wherein a main direction of extension of the trenches extends along the singulation lines in transverse direction and the trenches comprise the transitions.

Recesses adjacent in transverse direction can also be connected to one another by a channel. In contrast to the recesses, the channels are arranged in particular outside the resonator region. Via such a channel, an exchange of media between the individual recesses can be achieved during wet chemical etching. Furthermore, the wetting of the semiconductor material with the etching solution can also be improved. The depth of the channels may be the same as or different from the depth of the recesses. For example, a shallower depth may be sufficient for the channels than for the recesses.

According to at least one embodiment of the method, the resonator regions are ridge waveguides. The semiconductor layer sequence is structured in particular in the lateral direction in such a way that the ridge waveguide forms an elevation in which index guiding of the radiation propagating in the resonator can take place.

According to at least one embodiment of the method, the ridge waveguides have a widened region along the singulation lines in transverse direction. In the widened region, the extension in transverse direction is greater than the extension of the ridge waveguide in transverse direction in the remaining region. The widened region may extend in transverse direction to the singulation lines in the longitudinal direction or may be spaced from these singulation lines. Along the longitudinal direction, the extent of the widened region is preferably small compared to the extent of the semiconductor laser along that direction. For example, the extent of the widened region along the longitudinal direction within a device region is at most 20% or at most 10% or at most 2% of the extent of the device region or the semiconductor laser to be fabricated along that direction.

In particular, the recesses can be formed at least partially in the widened region. For example, the recesses can be formed along the transverse direction starting from a semiconductor material that is at the same height. This reduces the risk that the change in height at the edge of the ridge waveguide will affect the quality of the resonator surfaces to be produced.

The recesses can also be formed completely within the widened region. Thus, immediately after their formation, the recesses are surrounded along their entire circumference by semiconductor material that is at the same level. When subsequently singulating along the singulation lines in transverse direction passing through the respective recesses, semiconductor lasers can be fabricated in which each recess on the side opposite to the side face extending in transverse direction is surrounded along its circumference by semiconductor material which is at the same level. In other words, the recess is adjacent to semiconductor material located at the same level at each location spaced from the side face extending in transverse direction.

Alternatively, a recess may extend along the transverse direction beyond the associated widened region.

Furthermore, a semiconductor laser is specified. The method described above is suitable, for example, for manufacturing the semiconductor laser. Features described in connection with the method may therefore also apply to the semiconductor laser and vice versa.

According to at least one embodiment, the semiconductor laser has a semiconductor layer sequence and a resonator region, the semiconductor laser extending along the resonator region between two side faces running in transverse direction, the semiconductor laser having a resonator surface at each of the side faces running in transverse direction, which resonator surface is arranged offset with respect to the side faces.

The semiconductor laser has a recess along each of the transversely extending side faces, the recess having at least one transition at which, in plan view of the semiconductor laser, a first section of a side face of the recess and a second section of the side face of the recess enclose an angle of more than 180° in the recess.

In a top view of the semiconductor laser, the resonator surfaces are therefore not located on the side faces running in transverse direction. The distance between opposing resonator surfaces is here smaller than the length of the semiconductor chip along the longitudinal direction.

According to at least one embodiment of the semiconductor laser, the recess extends into a substrate of the semiconductor laser on which the semiconductor layer sequence of the semiconductor laser is arranged, for example deposited. In the vertical direction, the recess thus completely penetrates the semiconductor layer sequence.

According to at least one embodiment of the semiconductor laser, the resonator region is formed as a ridge waveguide.

According to at least one embodiment of the semiconductor laser, the ridge waveguide has a widened region in transverse direction. Thus, the resonator region is formed by a ridge waveguide having a widened region. For example, the widened region extends at least in places to the nearest side face extending in transverse direction. Alternatively, the widened region may be spaced from the side face extending in transverse direction at any location.

In a top view of the semiconductor laser, the recess may be located completely or only partially within the associated widened region. In the former case, the recess is surrounded along its circumference, in particular at the side opposite to the side face extending in transverse direction, by semiconductor material which is at the same level. In other words, the recess is adjacent to semiconductor material located at the same level at any location spaced from the associated side face extending in transverse direction.

### BRIEF DESCRIPTION OF THE DRAWING

Further embodiments and expediencies will become apparent from the following description of the embodiments in conjunction with the figures:

In the Figures:

FIGS. 1A to 1F show an exemplary embodiment of a method of manufacturing semiconductor lasers, wherein FIGS. 1A, 1B, 1C, 1E and 1F each schematically show an intermediate step in plan view, and FIG. 1D shows an enlarged view of a portion of FIG. 1C;

FIGS. 2A, 2B and 2C show in each case an exemplary embodiment for a method in each case by means of a schematic representation of an intermediate step in plan view;

FIGS. 3A and 3B show in each case an exemplary embodiment for a method in each case by means of a schematic representation of an intermediate step in plan view;

FIGS. 4A and 4B show in each case an exemplary embodiment for a method in each case by means of a schematic representation of an intermediate step in plan view;

FIGS. 5A, 5B, 5C and 5D show in each case an exemplary embodiment for a method in each case by means of a schematic representation of an intermediate step in plan view;

FIGS. 6A, 6B and 6C show in each case an exemplary embodiment for a method in each case by means of a schematic representation of an intermediate step in plan view; and

FIGS. 7A and 7B show an exemplary embodiment of a semiconductor laser in schematic top view (FIG. 7A) and corresponding side view (FIG. 7B).

### DETAILED DESCRIPTION

Elements that are identical, similar or have the same effect are each given the same reference signs.

The figures are each schematic representations and therefore not necessarily to scale. Rather, individual elements and in particular also layer thicknesses may be shown in exaggerated size for better understanding and/or for better representability.

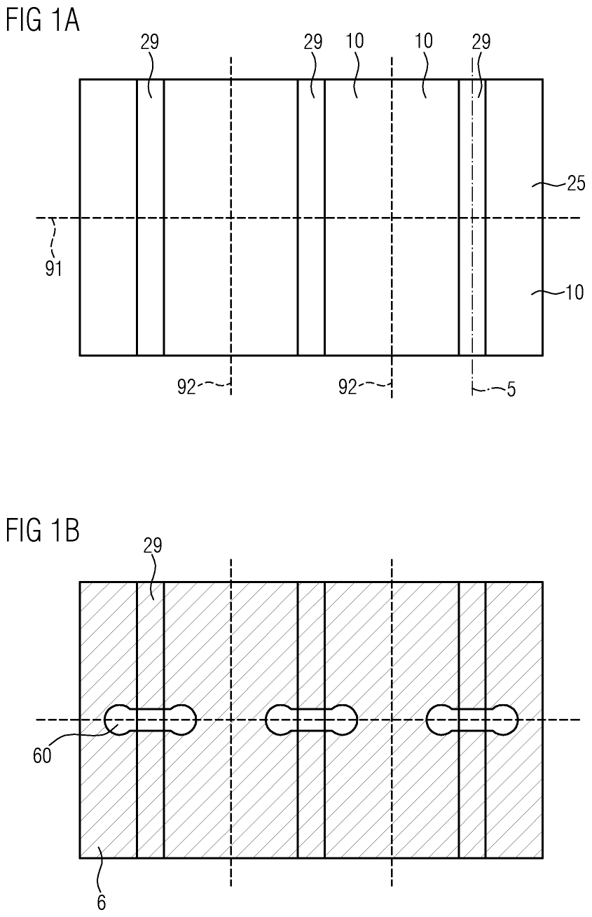

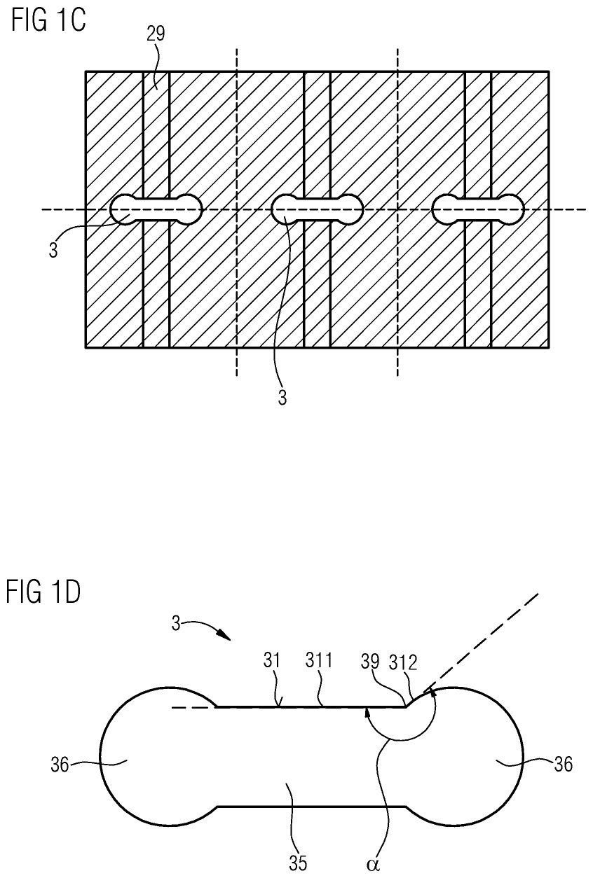

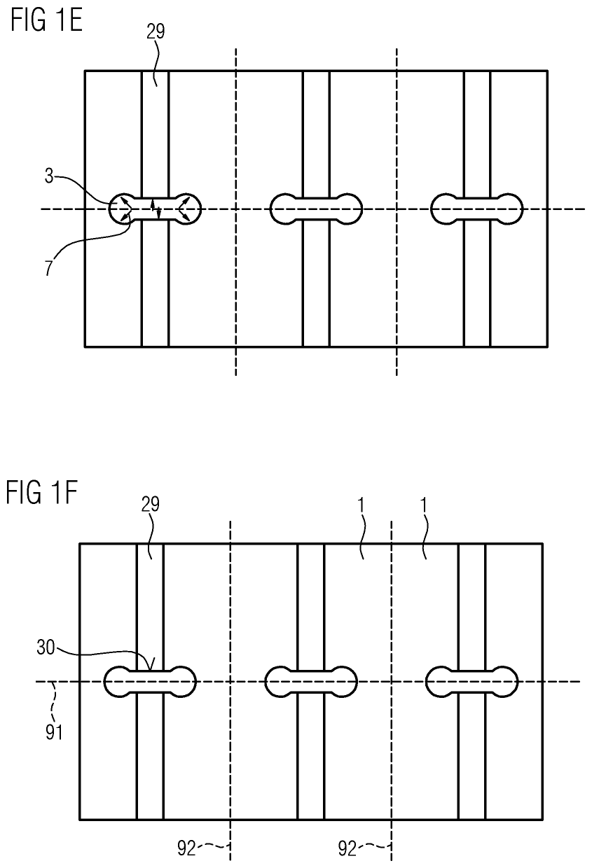

With reference to FIGS. 1A to 1F, an exemplary embodiment for a method of manufacturing a plurality of semiconductor lasers is shown in each case by means of a schematic representation in plan view. Here, a section of a substrate having six device regions 10 is shown. The device regions are each bounded by two singulation lines in transverse direction 91 and singulation lines extending perpendicularly thereto in the longitudinal direction 92.

A semiconductor layer sequence 2 is formed on the substrate 25, wherein the device regions 10 each have a resonator region 29. The substrate is, for example, a growth substrate for epitaxial deposition of the semiconductor layer sequence, such as GaN or sapphire for epitaxial deposition of a semiconductor layer sequence based on nitride compound semiconductor material.

Deviating from the described exemplary embodiment, a semiconductor laser 1 to be manufactured may also have more than one resonator region 29. The semiconductor lasers to be manufactured may be index-guided or gain-guided, for example. As illustrated in FIG. 1B, a mask 6 shown hatched in FIG. 1B is formed on the substrate 25 with a plurality of openings 60. The mask may be a photoresist mask or a hard mask, for example a SiN mask or a SiO₂ mask or a metallic mask, for example of Ti.

In the area of the openings 60, the substrate with the semiconductor layer sequence is subjected to a dry chemical etching process, for example a plasma etching process, so that the recesses 3 are formed in the area of the openings 60 (FIG. 1C). The shape of the openings 60 is transferred to the substrate with the semiconductor layer sequence. The recesses overlap with the singulation lines in transverse direction 91. The recesses 3 extend, for example, through the semiconductor layer sequence 2 into the substrate 25. FIG. 1D illustrates a recess 3 enlarged.

The recess 3 has a first partial region 35 and a second partial region 36 adjoining the first partial region. The first partial region 35 has a rectangular basic shape in plan view. The second partial region 36 has a larger extension than the first partial region 35, at least in places when viewed in the longitudinal direction. A side face 31 of the recess 3 has a transition 39. At the transition, a first section 311 of the side face 31 of the first partial region forms an angle α of more than 180° with a second section 312 of the side face 31 of the second partial region 36 in the recess. Thus, in the region of the transition 39, the recess 3 opens.

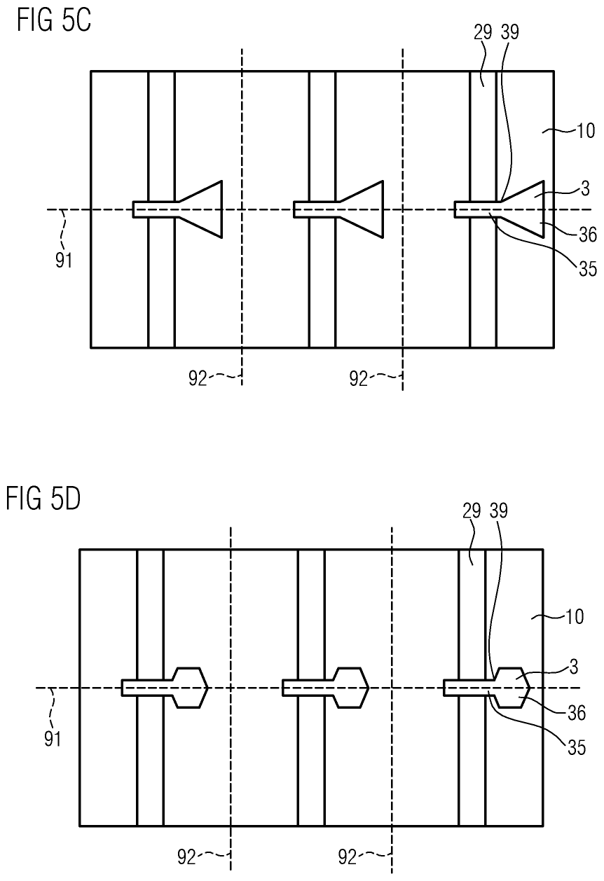

For example, the angle α between the first section 311 and the second section 312 of the side face 31 is between 180.001° and 359° inclusive, for example 200°, 235°, 270°, 300° or 335°. In the exemplary embodiment shown, the first partial region 35 is arranged between two second partial regions 36 when viewed in transverse direction. This results in a dumbbell-shaped basic form for the recess 3. However, the recess 3 can also have only one second partial region 36 (compare FIGS. 5A to 5D).

In FIG. 1D, the second partial region 36 is continuously curved, for example in the form of a part of a circle or an ellipse. However, the side face 31 can also be straight in places in the area of the second partial region 36, whereby kinks or bends can be present between straight sections.

In a subsequent step, the side faces 31 of the recesses 3 are wet-chemically etched, as schematically shown in FIG. 1E with arrows 7 for a recess 3, whereby resonator surfaces 30 are formed in the area of the resonator regions 29. The wet chemical etching is performed in such a way that it has a high selectivity with respect to the crystal directions of the semiconductor material, so that a crystal plane running perpendicular to the longitudinal direction of the semiconductor lasers to be manufactured is exposed. For example, a semiconductor laser with a semiconductor layer sequence based on nitride compound semiconductor material can be a (1-100) crystal plane.

At the time of wet chemical etching, the mask 6 may already have been removed, as shown in FIG. 1E. However, it may also be appropriate to remove the mask 6 only after the wet chemical etching.

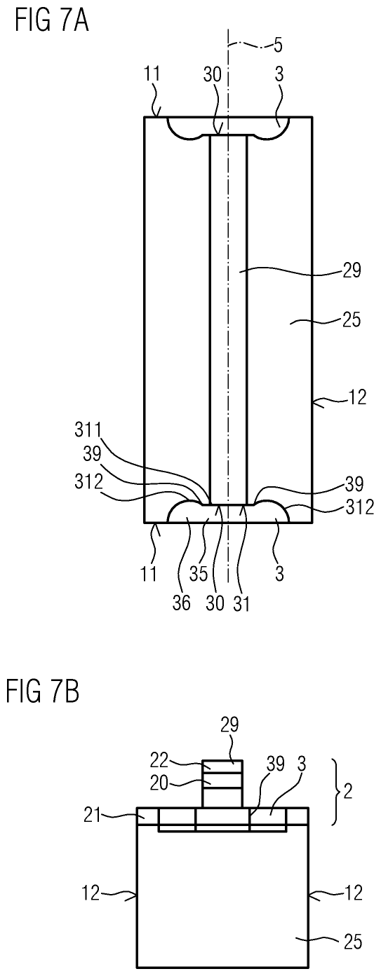

Subsequently, the substrate is singulated along the singulation lines in transverse direction 91 and the singulation lines in the longitudinal direction 92 (FIG. 1F). Along the singulation lines in transverse direction 91 side faces extending in transverse direction 11 are formed and along the singulation lines in longitudinal direction 92 side faces extending in longitudinal direction 12 of the respective semiconductor laser are formed (cf. FIG. 7A). At the time of singulation the resonator surfaces 30 are already formed, so that the singulation process itself has no direct influence on the quality of the resonator surfaces 30. As a result, there is a high degree of flexibility with respect to the singulation process. For example, the singulation can be performed mechanically, chemically or by means of laser radiation.

For nitride compound semiconductor material, in particular also for nitride compound semiconductor material with a comparatively high indium content, for example an indium content of more than 10%, it has been found that the resonator surfaces 30 can be produced with a particularly high quality if an angle greater than 180° is offered for the wet chemical etching process at the transition 39. The geometric shape of the recesses 3 with the transition 39 thus brings about a favorable change in the etching behavior, whereby particularly smooth resonator surfaces 30 with especially low roughness can be obtained.

In principle, the shape of the recesses 3 can be varied within wide limits. Here, the transition 39, as seen from a resonator axis of the closest resonator region 29 in transverse direction, is preferably the first point of the side face 31 at which the side face deviates from a straight course. The further course of the lateral surface 31, on the other hand, is of only secondary importance and can be straight and/or curved in sections, whereby further transitions between further sections can also include angles with one another which are smaller than 180°.

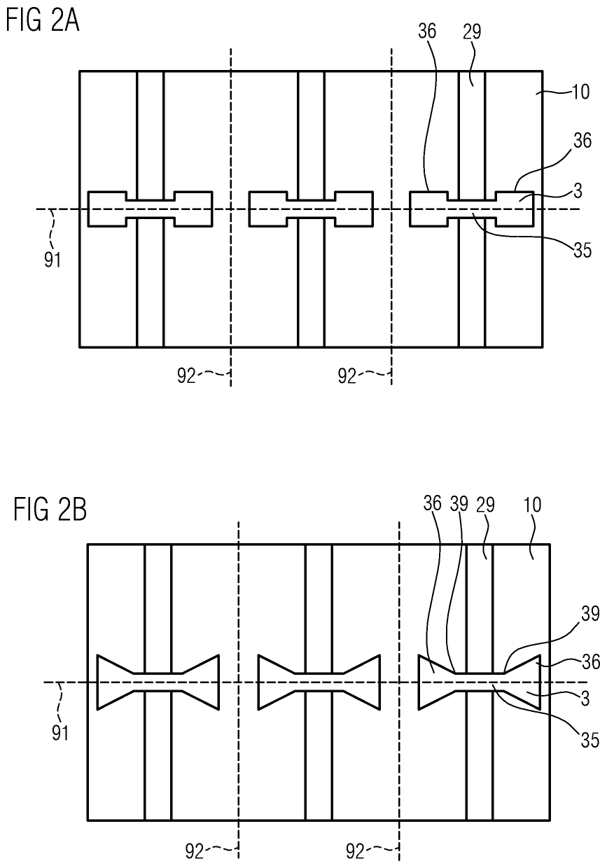

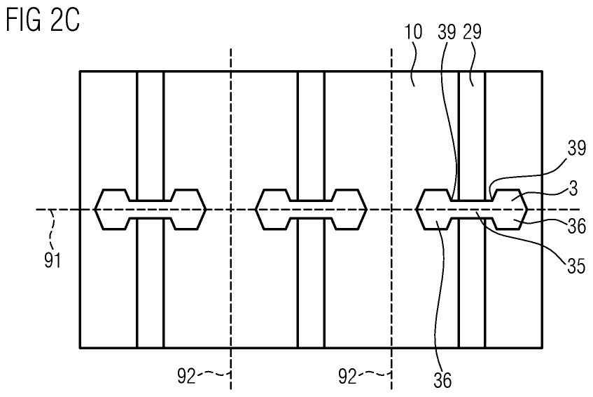

Further examples of shapes of the recesses 3 are shown in FIGS. 2A to 6C. The procedure described above can be carried out analogously for this configuration of the recesses.

In the exemplary embodiments shown in FIGS. 2A to 2C, the recesses 3 each have a dumbbell-shaped basic form with a first partial region 35 and two second partial regions 36 adjoining the first partial region 35 on opposite sides.

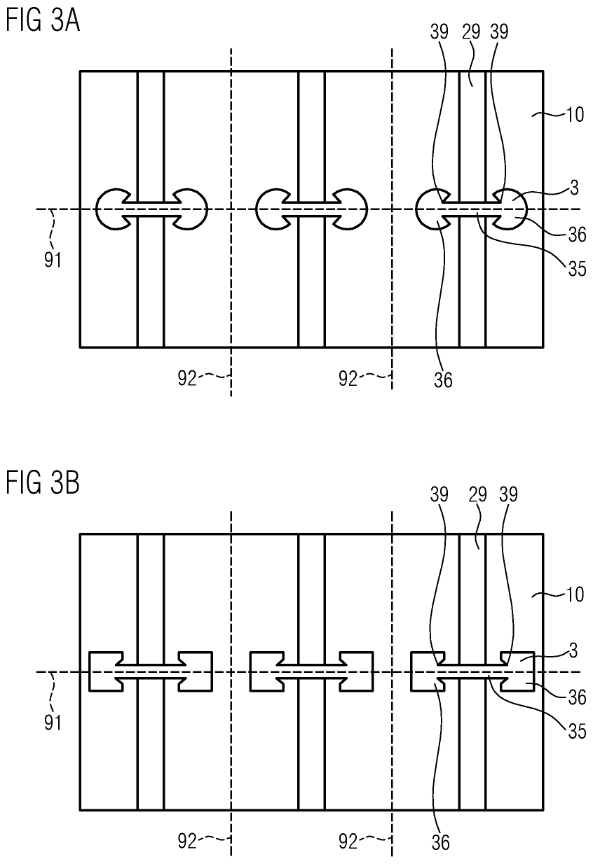

In the exemplary embodiment shown in FIG. 2A, the second partial regions 36 have a polygonal basic shape, such as a four-sided, for example a rectangular or a square basic shape. In FIG. 2A, the angle α=270°, but it may be less than 270° or greater than 270° (compare FIGS. 3A and 3B). The corners of the polygonal basic shape can also be rounded.

In the exemplary embodiment shown in FIG. 2B, the second partial regions 36 have a basic shape in which the extent of the recess 3 in the longitudinal direction increases with increasing distance from the associated resonator region 29, for example continuously. For example, the second partial region 36 has a trapezoidal basic shape with sections extending in a straight line. However, individual sections of the side face 31 may also extend in a curved manner in the second partial region 36.

In the exemplary embodiment shown in FIG. 2C, the second partial regions 36 each have a polygonal, for example hexagonal, basic shape, whereby the extension in the longitudinal direction initially increases with increasing distance from the resonator region 29 and subsequently decreases again. Between an increasing and a decreasing region, as shown in FIG. 2C, there may also be a region of the second sub-region in which the longitudinal extent remains constant.

FIGS. 3A and 3B show further exemplary embodiments of recesses 3 in which the angle α at the transition 39 is more than 270°.

In the exemplary embodiment shown in FIG. 3A, the side face 31 of the second partial region 36 is curved in places, such as in the form of a segment of a circle or an ellipse segment, when viewed from above.

In the exemplary embodiment shown in FIG. 3B, the second partial regions 36 have a polygonal basic shape, such as an octagonal basic shape as shown in FIG. 3B. The side face 31 of the second partial region 36 may also have portions that are partially curved and portions that are partially straight.

With an angle of α>270° at the transition 39, the transition 39 is expediently spaced from the resonator region 29 located closest to it to such an extent that the second partial region 36 is arranged without overlapping with respect to the resonator region 29 in plan view. Seen along the longitudinal direction, the first partial region 35 and the second partial region 36 overlap in places.

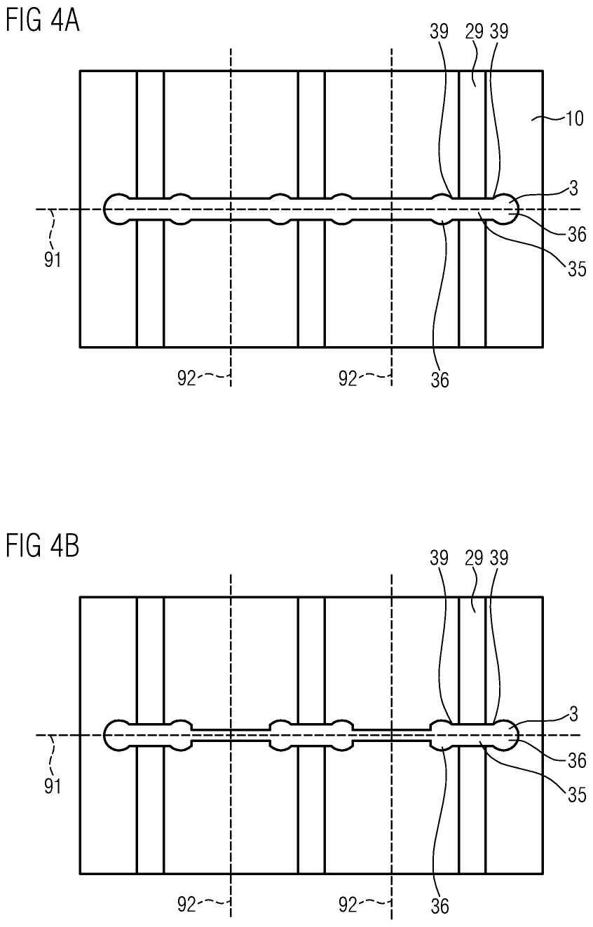

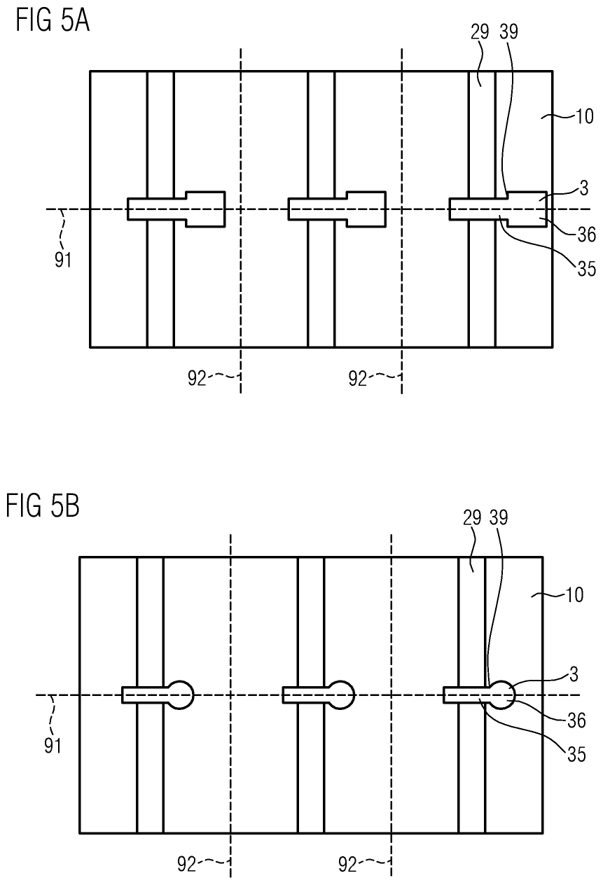

FIGS. 4A and 4B illustrate embodiments of recesses 3 that extend continuously across adjacent device regions 10 along the transverse direction.

In the exemplary embodiment shown in FIG. 4A, the second partial regions 36 of adjacent device regions 10 are each connected by a partial region having the same longitudinal extent as the first sub-region. In the exemplary embodiment shown in FIG. 4B, the second partial regions 36 of adjacent device regions 10 are connected to each other by a channel 4.

The channel 4 may extend in each case along the transverse direction over two or more, in particular also over all, device regions 10. The depth of the channels 4 may correspond to the depth in the remaining area of the recesses 3 or may be smaller or larger. Media can be exchanged during the wet chemical etching process via continuously extending recesses 3, for example in the form of trenches, or via the channels 4. This simplifies a uniform formation of the individual resonator surfaces in the lateral direction across the substrate 25 for the semiconductor lasers 1 to be manufactured. The geometry with recesses 3 extending continuously over adjacent device regions can be combined with the above-described configurations of the second partial regions 36.

FIGS. 5A to 5D illustrate exemplary embodiments in which the recesses 3 each have a transition 39 on only one side of the associated resonator region 29. The recesses 3 have only one second partial region 36. For this second partial region 36, the explanations for FIG. 2A apply to FIG. 5A, the explanations for FIG. 1D apply to FIG. 5B, the explanations for FIG. 2B apply to FIG. 5C, and the explanations for FIG. 2C apply to FIG. 5D.

The asymmetrical design of the recesses 3 described in connection with FIGS. 5A to 5D with respect to the resonator axis 5 of the resonator regions 29 can also be combined with the embodiments according to FIGS. 4A and 4B.

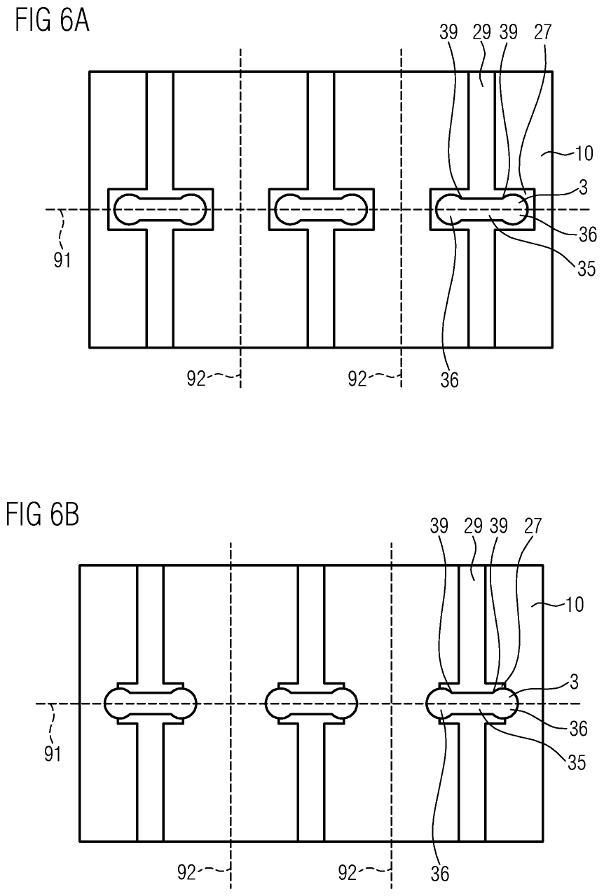

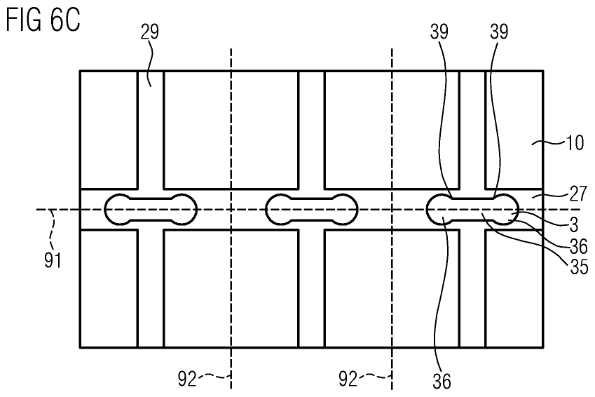

In the exemplary embodiments according to FIGS. 6A to 6C, the resonator region 29 is a ridge waveguide in each case, which has a widened region 27. In the widened region 27, the ridge waveguide has a larger width in transverse direction than in the remaining region. In the vertical direction, the widened region 27 has the same thickness as the rest of the resonator region 29.

In each of the exemplary embodiments shown in FIGS. 6A and 6B, the widened region 27 is spaced from the singulation lines in the longitudinal direction 92.

Here, in the exemplary embodiment shown in FIG. 6A, the recess 3 is arranged completely within the widened region 27. In FIGS. 6A to 6C, the recesses 3 each have a basic shape as described in connection with FIG. 1D. However, other basic shapes may also be used, in particular shapes according to the embodiments of FIGS. 2A to 3B. Furthermore, the recesses 3 may extend continuously between adjacent device regions 10, as described in connection with FIGS. 4A and 4B. Also, a configuration as described in connection with FIGS. 5A to 5D is possible for the recesses 3.

As shown in FIG. 6A, the recesses 3 can each be formed to be entirely within the widened region 27. Thus, the recesses 3 are surrounded along their entire circumference by semiconductor material which is at the same level prior to the dry chemical etching process. This can reduce the risk that the elevation formed by the resonator region 29, which is designed as a ridge waveguide, will cause interference with the resonator surface 30 to be formed.

In the exemplary embodiment shown in FIG. 6B, the recesses 3 have a larger extension in transverse direction than the widened region 27. Here, the transition 39 is located within the widened region 27. Thus, at least the first section 311 of the recess, which is decisive for the formation of the resonator surface 30, can be located within the widened region 27.

In the exemplary embodiment shown in FIG. 6C, the widened region 27 extends continuously across adjacent device regions when viewed from above onto the substrate. Thus, the widened region 27 overlaps with the singulation lines in longitudinal direction 92.

The exemplary embodiment with a widened region 27 described in connection with FIGS. 6A to 6C can be combined with the above exemplary embodiments of the method.

FIGS. 7A and 7B illustrate an exemplary embodiment of a semiconductor laser in schematic top view and associated side view. Exemplarily, a semiconductor laser is shown that can be fabricated as described in connection with FIGS. 1A to 1F. However, the exemplary embodiments described in connection with the various exemplary embodiments for the method, for example, for resonator regions having a widened region 27 (cf. FIGS. 6A to 6C) and/or the embodiment of the recesses 3 (cf. FIGS. 2A to 5D) are analogously applicable to the semiconductor laser 1.

The semiconductor laser 1 comprises a substrate 25 and a semiconductor layer sequence 2 arranged on the substrate 25. The semiconductor layer sequence has an active region 20 arranged between a first semiconductor layer 21 of a first conductivity type and a second semiconductor layer 22 of a second conductivity type, such that the active region is located in a pn junction. For example, the first semiconductor layer is n-type and the second semiconductor layer 22 is p-type. The first semiconductor layer 21 and the second semiconductor layer 22 may also have the same conductivity type, for example, in a semiconductor laser 1 designed as an interband cascade laser or a semiconductor laser 1 designed as a quantum cascade laser. Contact areas for external electrical contacting of the first semiconductor layer 21 and the second semiconductor layer 22 are not explicitly shown in FIG. 7B for simplified illustration.

The semiconductor laser 1 comprises a resonator region 29, wherein the semiconductor laser 1 extends in the longitudinal direction, i.e. along a resonator axis 5, between two side faces 11 extending in transverse direction. Perpendicular to this, the semiconductor laser 1 has side faces extending in the longitudinal direction 12. In the exemplary embodiment shown, the resonator region 29 is formed as a ridge waveguide. The active region 20 may be arranged in the ridge waveguide or below the ridge waveguide.

However, departing from a ridge waveguide configuration, the resonator region 29 can also be a region of the semiconductor laser 1 in which the radiation oscillates in the resonator in a gain-guided manner.

At each of the side faces extending in transverse direction 11, the semiconductor laser has a resonator surface 30 which is arranged offset from the side faces extending in transverse direction 11 of the semiconductor laser 1. The resonator surfaces 30 bound the resonator region 29 on two opposite sides as viewed along the resonator axis 5.

Furthermore, the semiconductor laser 1 has a recess 3, wherein a side face 31 of the recess forms the resonator surface 30. The recess 3 extends into the substrate 25 in vertical direction, i.e. perpendicular to the main extension plane of the semiconductor layer sequence 2.

A side face 31 of the recess has a transition 39 between a first section 311 and a second section 312 on each side of the resonator region 29, as viewed in transverse direction. At the transition 39, an angle of the side face 31 is more than 180° as viewed from above onto the semiconductor laser. The first section 311 forms the resonator surface 30 and is perpendicular to the resonator axis. The second section 312 may be directly adjacent to the resonator region 29 in transverse direction or may be spaced from the resonator region 29 in transverse direction, for example by at most 100 μm or at most 30 μm or at most 10 μm or at most 5 μm or at most 1 μm. In operation of the semiconductor laser 1, most of the laser radiation propagating in the resonator region 29, for example at least 80%, emerges from the first section 311.

The first section 311 is formed by a first partial region 35 of the recess 31. The first partial region has a rectangular cross-section. A second partial region 36 adjoins the first partial region 35 in both directions, as seen in transverse direction, and has a greater extent along the longitudinal direction than the first partial region 35, at least in some areas. Various basic shapes with bends and/or kinks can be used for the second partial region 36, for example the basic shapes described in connection with FIGS. 2A to 3B.

The geometry of the recess 31 can positively influence the etching behavior during the production of the resonator surfaces 30, so that particularly smooth resonator surfaces can be produced. An average roughness of the resonator surfaces is, for example, at most 50 nm, preferably at most nm, particularly preferably at most 10 nm.

Deviating from the shown exemplary embodiment, such a transition 39 may also be present only on one side of the resonator region 29, as described in connection with FIGS. 5A to 5D.

Furthermore, deviating from the exemplary embodiment shown, the recess 3 can also be formed in the area of a widened region 27 of the resonator region 29 designed as a ridge waveguide. For example, on the side opposite to the side face extending in transverse direction 11, the recess 3 is surrounded along its circumference by semiconductor material which is at the same level. In other words, the recess 3 is adjacent to semiconductor material that is at the same height at any location spaced from the side face extending in transverse direction 11. Where appropriate, the widened region 27 may be spaced from the side faces in longitudinal direction (cf. FIG. 6A) or it may extend to the side faces in the longitudinal direction 12 so that the widened region 27 has the same extent in transverse direction as the semiconductor laser 1 (cf. FIG. 6C). Similarly, the recess 3 may also extend to the side faces extending in longitudinal direction 12.

Furthermore, a semiconductor laser 1 may also have multiple resonator regions 29.

The invention is not limited by the description based on the exemplary embodiments. Rather, the invention encompasses any new feature as well as any combination of features, which in particular includes any combination of features in the claims, even if this feature or combination itself is not explicitly stated in the claims or the exemplary embodiments.

1. A method of manufacturing a plurality of semiconductor lasers comprising:
a) providing a substrate with a semiconductor layer sequence and with a plurality of device regions, each device region having at least one resonator region and being bounded perpendicularly to the resonator region by singulation lines in transverse direction and parallel to the resonator region by singulation lines in longitudinal direction;
b) forming recesses which overlap with the singulation lines in transverse direction by a dry chemical etching process, the recesses each having at least one transition at which, in plan view of the substrate, a first section of a side face of the recess and a second section of the side face of the recess enclose an angle of more than 180° in the recess;
(c) wet chemical etching of the side faces of the recesses to form resonator surfaces; and
d) singulating the substrate along the singulation lines in transverse direction and in the longitudinal direction.

2. The method according to claim 1,
wherein the side faces of the recesses in the transition are each curved or kinked.

3. The method according to claim 1,
wherein the transition, viewed from a resonator axis of the closest resonator region in transverse direction, is the first point on the side face where the side face deviates from a straight course.

4. The method according to claim 1,
wherein the transition is arranged between a first partial region of the recess and a second partial region of the recess, wherein by means of the first partial region the resonator surface is formed and the second partial region has at least in places a larger extension in longitudinal direction than the first partial region.

5. The method according to claim 1, wherein the angle at the transition is between 180.001° and 359°, inclusive.

6. The method according to claim 1, wherein a distance between the transition and the closest resonator region is at most 100 μm.

7. The method according to claim 1, wherein at least in the region of the resonator regions a crystal plane extending perpendicular to the resonator region is exposed in step c).

8. The method according to claim 1, wherein the semiconductor layer sequence is based on a nitride compound semiconductor material, and in step c) a (1-100) plane or a (1-10) plane of the semiconductor layer sequence is exposed.

9. The method according to claim 1, wherein the recesses in step b) are formed so as to be spaced from the singulation lines in longitudinal direction.

10. The method according to claim 1, wherein the recesses between adjacent device regions extend continuously across the singulation lines in longitudinal direction.

11. The method according to claim 1, wherein the resonator regions are ridge waveguides, the ridge waveguides having a widened region along the singulation lines in transverse direction and the recesses being formed at least in part in the widened region.

12. The method according to claim 11, wherein the recesses are formed entirely within the widened region.

13. The method according to claim 1, wherein the second section is curved at least in places.

14. A semiconductor laser comprising a semiconductor layer sequence and a resonator region E, wherein
the semiconductor laser extends along the resonator region between two side faces extending in transverse direction;
the semiconductor laser has a resonator surface at each of the side faces extending in transverse direction, the resonator surface being arranged offset from the side faces extending in transverse direction of the semiconductor laser, and
the semiconductor laser has a recess along each of the side faces extending in transverse direction, the recess having at least one transition at which, in plan view of the semiconductor laser, a first section of a side face of the recess and a second section of the side face of the recess enclose an angle of more than 180° in the recess.

15. The semiconductor laser according to claim 14,
wherein the recess extends into a substrate of the semiconductor laser on which the semiconductor layer sequence is arranged.

16. The semiconductor laser according to claim 14,
wherein the resonator region is a ridge waveguide having a transversely widened portion.

17. (canceled)

18. A method of manufacturing a plurality of semiconductor lasers comprising:
a) providing a substrate with a semiconductor layer sequence and with a plurality of device regions, each device region having at least one resonator region and being bounded perpendicularly to the resonator region by singulation lines in transverse direction and parallel to the resonator region by singulation lines in longitudinal direction;
b) forming recesses which overlap with the singulation lines in transverse direction by a dry chemical etching process, the recesses each having at least one transition at which, in plan view of the substrate, a first section of a side face of the recess and a second section of the side face of the recess enclose an angle of more than 180° in the recess;
(c) wet chemical etching of the side faces of the recesses to form resonator surfaces; and
d) singulating the substrate along the singulation lines in transverse direction and in the longitudinal direction;
wherein
(i) the resonator regions are ridge waveguides, wherein the ridge waveguides comprise a widened region along the singulation lines in transverse direction and the recesses are formed entirely within the widened region; and/or
(ii) the second section is curved at least in places.
